(19) United States
(12) Patent Application Publication
(10) Pub. No.: US 2019/0221664 A1
(43) Pub. Date: Jul. 18, 2019

(54) MOSFET AND POWER CONVERSION CIRCUIT

(71) Applicant: SHINDENGEN ELECTRIC MANUFACTURING CO., LTD., Chiyoda-ku, Tokyo (JP)

(72) Inventors: Daisuke ARAI, Saitama (JP); Shigeru HISADA, Saitama (JP); Mizue KITADA, Saitama (JP); Takeshi ASADA, Saitama (JP)

(21) Appl. No.: 16/329,308

(22) PCT Filed: Sep. 2, 2016
(86) PCT No.: PCT/JP2016/075870

§ 371 Date: Feb. 28, 2019

(51) Int. Cl. H01L 29/78; H01L 29/06; H01L 29/36; H01L 29/16; H01L 29/423; H02M 3/155

(52) U.S. Cl. CPC H01L 29/7813; H01L 29/0634; H01L 29/36; H01L 29/7811; H01L 29/0878; H01L 29/1608; H01L 29/4236; H01L 29/7803; H02M 3/155; H01L 29/7806

(57) ABSTRACT

A MOSFET used in a power conversion circuit having a reactor, a power source, the MOSFET, and a rectifier element, includes a semiconductor base substrate with a super junction structure formed of an n-type column region and a p-type column region. A total amount of a dopant in the n-type column region is higher than a total amount of a dopant in the p-type column region. The MOSFET is configured to be operated during a period from a point of time when a drain current starts to decrease to a point of time when the drain current becomes 0 for the first time in response to turning off of the MOSFET such that a first period during which the drain current decreases, a second period during which the drain current increases, and a third period during which the drain current decreases again appear in this order.

### RELATED APPLICATIONS

The present application is a National Phase of International Application Number PCT/JP2016/075870, filed Sep. 2, 2016.

### TECHNICAL FIELD

The present invention relates to a Metal-Oxide Semiconductor Field-Effect Transistor (MOSFET) and a power conversion circuit.

### BACKGROUND ART

Conventionally, there has been known a MOSFET which includes a semiconductor base substrate where a super junction structure is formed of an n-type column region and a p-type column region (see patent document 1, for example).

In this specification, “super junction structure” means a structure where an n-type column region and a p-type column region are alternately and repeatedly arranged as viewed in a predetermined cross section.

As shown in FIG. 16, a conventional MOSFET 900 includes: a semiconductor base substrate 910 having n-type column regions 914, p-type column regions 916, a p-type base region 918 formed on surfaces of the n-type column regions 914 and surfaces of the p-type column regions 916, and an n-type source region 920 formed on a surface of the base region 918 and where a super junction structure is formed of the n-type column regions 914 and the p-type column regions 916; trenches 922 which are formed so as to reach a depth position deeper than a deepest portion of the base region 918 in regions where the n-type column region 914 is positioned as viewed in a plan view and a part of the source region 920 is exposed on an inner peripheral surface of the trench 922; and gate electrodes 926 which are embedded in the inside of the trenches 922 through gate insulation films 924 formed on inner peripheral surfaces of the trenches 922.

In the conventional MOSFET 900, the n-type column region 914 and the p-type column region 916 are formed such that a total amount of a dopant in the n-type column region 914 is equal to a total amount of a dopant in the p-type column region 916. That is, the n-type column region 914 and the p-type column region 916 are well-balanced with each other in terms of a charge.

The conventional MOSFET 900 includes the semiconductor base substrate 910 where the super junction structure is formed of the n-type column regions 914 and the p-type column regions 916 thus providing a switching element which has a low ON resistance and a high withstand voltage.

### PRIOR ART DOCUMENT

### Patent Document

Patent document 1: JP-A-2012-64660

Patent document 2: JP-A-2012-143060

### SUMMARY OF INVENTION

### Problem to be Solved by the Invention

The above-mentioned conventional MOSFET 900 is used as a switching element having a low ON resistance and a high withstand voltage and hence, the use of the MOSFET 900 in a power conversion circuit is considered (see patent document 2, for example). However, in the case where the conventional MOSFET is used in the power conversion circuit, when the MOSFET is turned off, there is a tendency for a surge voltage to be increased. Accordingly, it is difficult for the MOSFET 900 to satisfy a standard for a surge voltage which a power conversion circuit is required to possess and hence, there exists a drawback that the applying of the MOSFET 900 to various power conversion circuits is difficult.

Accordingly, the present invention has been made so as to overcome the above-mentioned drawback, and it is an object of the present invention to provide a MOSFET capable of being applied to various power conversion circuits, and a power conversion circuit which uses the MOSFET.

### Solution to Problem

[1] According to the present invention, there is provided a MOSFET used in a power conversion circuit which includes at least a reactor, a power source which supplies an electric current to the reactor, the MOSFET for controlling an electric current supplied from the power source to the reactor, and a rectifier element which performs a rectifying operation of the electric current supplied from the power source to the reactor or an electric current from the reactor, wherein the MOSFET includes a semiconductor base substrate having an n-type column region and a p-type column region, the n-type column region and the p-type column region forming a super junction structure,

the n-type column region and the p-type column region are formed such that a total amount of a dopant in the n-type column region is set higher than a total amount of a dopant in the p-type column region, and

the MOSFET is configured to be operated during a period from a point of time when a drain current starts to decrease to a point of time when the drain current becomes 0 for the first time in response to turning off of the MOSFET such that a first period during which the drain current decreases, a second period during which the drain current increases, and a third period during which the drain current decreases again appear in this order.

In the specification, “total amount of a dopant” means a total amount of a dopant in a constitutional element (the n-type column region or the p-type column region) in the MOSFET.

[2] According to the MOSFET of the present invention, it is preferable that the total amount of the dopant in the n-type column region be set in a range of 1.05 times to 1.15 times as much as the total amount of the dopant in the p-type column region.

[3] According to the MOSFET of the present invention, it is preferable that a decrease amount of the drain current per unit time during the third period be set smaller than a decrease amount of the drain current per unit time during the first period.

[4] According to the MOSFET of the present invention, it is preferable that the MOSFET be configured to be operated such that, in response to turning off of the MOSFET, a period during which a gate-source voltage is temporarily increased appears after a mirror period is finished.

[5] According to the MOSFET of the present invention, it is preferable that the semiconductor base substrate further include: a p-type base region formed on a surface of the n-type column region and a surface of the p-type column region; and an n-type source region formed on a surface of the base region, and

the MOSFET be a trench-gate-type MOSFET which further includes: a trench where the trench is formed so as to reach a depth position deeper than a deepest portion of the base region in a region where the n-type column region is positioned as viewed in a plan view, and a portion of the source region is exposed on an inner peripheral surface of the trench; and

a gate electrode embedded in the inside of the trench by way of a gate insulation film formed on the inner peripheral surface of the trench.

[6] According to the MOSFET of the present invention, it is preferable that the semiconductor base substrate further include: a p-type base region formed on a surface of a portion of the n-type column region and a whole surface of the p-type column region; and an n-type source region formed on a surface of the base region, and the MOSFET be a planar-gate-type MOSFET which further includes a gate electrode formed on the base region sandwiched between the source region and the n-type column region by way of a gate insulation film.

[7] According to the MOSFET of the present invention, it is preferable that the semiconductor base substrate further include an n-type surface high concentration diffusion region formed on a portion of the surface of the n-type column region where the base region is not formed.

[8] According to the MOSFET of the present invention, it is preferable that in the p-type column region, in a depth direction of the p-type column region, a width of the p-type column region be increased as the p-type column region extends from a deep portion of the p-type column region toward a surface of the p-type column region (that is, the p-type column region having the structure where the width of the p-type column region is gradually increased as the p-type column region extends from the deep portion of the p-type column region toward the surface of the p-type column region).

[9] According to the MOSFET of the present invention, it is preferable that in the p-type column region, in a depth direction of the p-type column region, dopant concentration in the p-type column region be increased as the p-type column region extends from a deep portion of the p-type column region toward a surface of the p-type column region (that is, the p-type column region having the structure where dopant concentration in the p-type column region is gradually increased as the p-type column region extends from the deep portion of the p-type column region toward the surface of the p-type column region).

[10] According to the present invention, there is provided a power conversion circuit including at least: a reactor; a power source which supplies an electric current to the reactor; the MOSFET according to any one of [1] to [9] for controlling an electric current supplied from the power source to the reactor, and a rectifier element which performs a rectifying operation of the electric current supplied from the power source to the reactor or an electric current from the reactor.

[11] According to the power conversion circuit of the present invention, it is preferable that the rectifier element be a fast recovery diode.

[12] According to the power conversion circuit of the present invention, it is preferable that the rectifier element be a built-in diode of the MOSFET.

[13] According to the power conversion circuit of the present invention, it is preferable that the rectifier element be a silicon-carbide Schottky barrier diode.

### Advantageous Effects of the Present Invention

According to the MOSFET and the power conversion circuit of the present invention, the n-type column region and the p-type column region are formed such that a total amount of a dopant in the n-type column region is set higher than a total amount of a dopant in the p-type column region, and the MOSFET is configured to be operated during a period from a point of time when a drain current starts to decrease to a point of time when the drain current becomes 0 for the first time in response to turning off of the MOSFET such that a first period during which the drain current decreases, a second period during which the drain current increases, and a third period during which the drain current decreases again appear in this order. Accordingly, compared to the conventional MOSFET 900, a time until a current value of a drain current becomes 0 can be extended and, at the same time, a decrease amount of a drain current per unit time during the third period can be made small (see Id of the present invention example shown in FIG. 3A, FIG. 3B, FIG. 4A and FIG. 4B). Accordingly, a surge voltage of the MOSFET can be made smaller than a surge voltage of the conventional MOSFET 900 and hence, the power conversion circuit according to the present invention can easily satisfy a standard for a surge voltage which the power conversion circuit is required to possess. As a result, the MOSFET and the power conversion circuit according to the present invention are applicable to various power conversion circuits.

Further, according to the MOSFET and the power conversion circuit according to the present invention, as described above, compared to the conventional MOSFET 900, a time until a drain-source voltage Vds becomes maximum can be extended and, at the same time, an amount of increment per unit time of the drain-source voltage Vds until the drain-source voltage Vds becomes maximum can be made small and hence, oscillation minimally occurs compared to the conventional MOSFET 900.

Further, according to the MOSFET of the present invention, the MOSFET includes the semiconductor base substrate where the super junction structure is formed of the n-type column region and the p-type column region and hence, it is possible to provide a switching element having a low ON resistance and a high withstand voltage in the same manner as the conventional MOSFET 900.

### BRIEF DESCRIPTION OF DRAWINGS

FIG. 1 is a circuit diagram showing a power conversion circuit 1 according to Embodiment 1.

FIG. 2 is a cross-sectional view of a MOSFET 100 according to Embodiment 1.

FIG. 3A and FIG. 3B are graphs showing a time transition simulation result of a drain current Id, a drain-source voltage Vds, and a gate-source voltage Vgs, when a MOSFET is turned off in the power conversion circuit 1 according to Embodiment 1. FIG. 3A is the graph showing a time transition simulation result of the drain current Id and the drain-source voltage Vds when the MOSFET is turned off, and FIG. 3B is the graph showing a time transition simulation result of the gate-source voltage Vgs when the MOSFET is turned off. The MOSFET of the present invention example is the MOSFET 100 according to Embodiment 1, and the MOSFET of the Comparative example is a MOSFET where a total amount of a dopant in a p-type column region is set to 1.10 time as much as a total amount of a dopant in an n-type column region (the understanding being the same in FIG. 4A and FIG. 4B, FIG. 6A and FIG. 6B). A power source voltage is set to 300V.

FIG. 4A and FIG. 4B are graphs enlarging main parts shown in FIG. 3A and FIG. 3B. FIG. 4A is a graph enlarging the main part shown in FIG. 3A, and FIG. 4B is a graph enlarging the main part shown in FIG. 3B.

FIG. 5 is a graph showing a time transition simulation result of a drain current Id, and an electron current component and a hole current component of the drain current Id, when a MOSFET is turned off in a case where the MOSFET 100 according to Embodiment 1 is used as the MOSFET.

FIG. 6A and FIG. 6B are graphs showing a simulation result of a change in electrostatic potential in a depth direction of an n-type column region 114 when a MOSFET is turned off. FIG. 6A is a graph showing a simulation result of a change in electrostatic potential in a depth direction of the n-type column region 114 when the MOSFET is turned off in a case where the MOSFET of the present invention example is used as the MOSFET, and FIG. 6B is a graph showing a simulation result of a change in electrostatic potential in a depth direction of the n-type column region when the MOSFET is turned off in a case where the MOSFET of Comparative example is used as the MOSFET. FIG. 6A and FIG. 6B show the simulation result of a change in electrostatic potential of a portion indicated by a broken line taken along a line A1-A2 in FIG. 2, and a depth position of a lowermost portion of the gate electrode 126 (an interface between a gate electrode 126 and a gate insulation film 124) is set to 0 μm. Symbols (A) to (E) in FIG. 6A and FIG. 6B respectively indicate electrostatic potentials at respective points of time (A) to (E) in FIG. 5.

FIG. 7A to FIG. 7C are views showing operational states of a power conversion circuit 1, the MOSFET 100, and a rectifier element 30, when the MOSFET 100 is in an ON state. FIG. 7A is a circuit diagram showing an operational state of the power conversion circuit 1, FIG. 7B is a view showing an operational state of the MOSFET 100, and FIG. 7C is a view showing an operational state of the rectifier element 30 (the understanding is also the same in FIG. 8A to FIG. 11C.

FIG. 8A to FIG. 8C are views showing operational states of the power conversion circuit 1, the MOSFET 100, and the rectifier element 30 during a first period.

FIG. 9A to FIG. 9C are views showing operational states of the power conversion circuit 1, the MOSFET 100, and the rectifier element 30 during a second period.

FIG. 10A to FIG. 10C are views showing operational states of the power conversion circuit 1, the MOSFET 100, and the rectifier element 30 during a third period.

FIG. 11A to FIG. 11C are views showing operational states of the power conversion circuit 1, the MOSFET 100, and the rectifier element 30 when the MOSFET 100 is in an OFF state.

FIG. 12 is a circuit diagram showing a power conversion circuit 2 according to Modification 1. In FIG. 12, symbol 40 indicates a load, and symbol 50 indicates a capacitor.

FIG. 13 is a circuit diagram showing a power conversion circuit 3 according to Modification 2. In FIG. 13, symbol 40 indicates a load, and symbol 50 indicates a capacitor.

FIG. 14 is a cross-sectional view showing a MOSFET 102 according to Embodiment 2.

FIG. 15 is a circuit diagram showing a power conversion circuit 4 according to Embodiment 3.

FIG. 16 is a cross-sectional view showing a conventional MOSFET 900. Symbol 912 indicates a low-resistance semiconductor layer.

### DESCRIPTION OF EMBODIMENTS

Hereinafter, a MOSFET and a power conversion circuit according to the present invention are described in accordance with embodiments shown in the drawings. The respective drawings are schematic drawings, and do not always strictly reflect actual sizes of the MOSFET and the power conversion circuit.

### Embodiment 1

### 1. Structure and Operation of Power Conversion Circuit 1 According to Embodiment 1

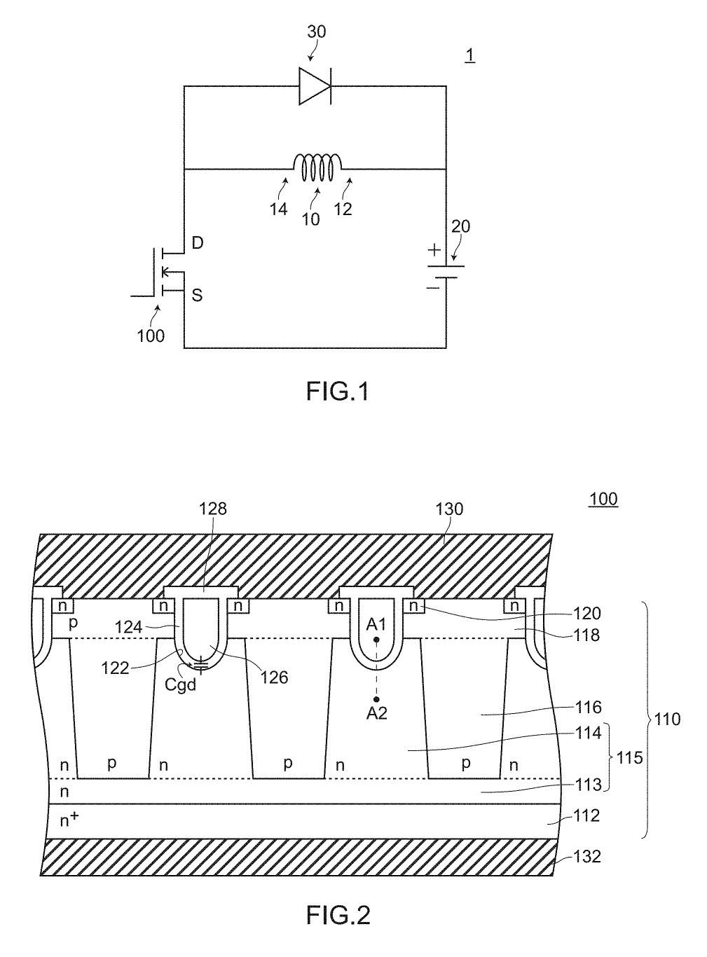

A power conversion circuit 1 according to Embodiment 1 is a chopper circuit which is a constitutional element such as a DC-DC converter or an inverter. The power conversion circuit 1 according to Embodiment 1 includes, as shown in FIG. 1, a reactor 10, a power source 20, a MOSFET 100 according to Embodiment 1, and a rectifier element 30.

The reactor 10 is a passive element which can store energy in a magnetic field generated by an electric current which flows through the reactor 10.

The power source 20 is a DC power source which supplies an electric current to the reactor 10. The MOSFET 100 controls an electric current supplied from the power source 20 to the reactor 10. To be more specific, the MOSFET 100 is switched to assume an ON state in response to a clock signal applied from a drive circuit (not shown in the drawing) to a gate electrode of the MOSFET 100, and electrically interconnects the reactor 10 and a negative pole of the power source 20. The specific structure of the MOSFET 100 is described later.

The rectifier element 30 is a silicon fast recovery diode (Si-FRD) which performs a rectifying operation of an electric current supplied from the power source 20 to the reactor 10. To be more specific, the rectifier element 30 is a lifetime-controlled PIN diode.

A positive pole (+) of the power source 20 is electrically connected to one end 12 of the reactor 10 and a cathode electrode of the rectifier element 30, and a negative pole (−) of the power source 20 is electrically connected to a source electrode of the MOSFET 100. A drain electrode of the MOSFET 100 is electrically connected to the other end 14 of the reactor 10 and an anode electrode of the rectifier element 30.

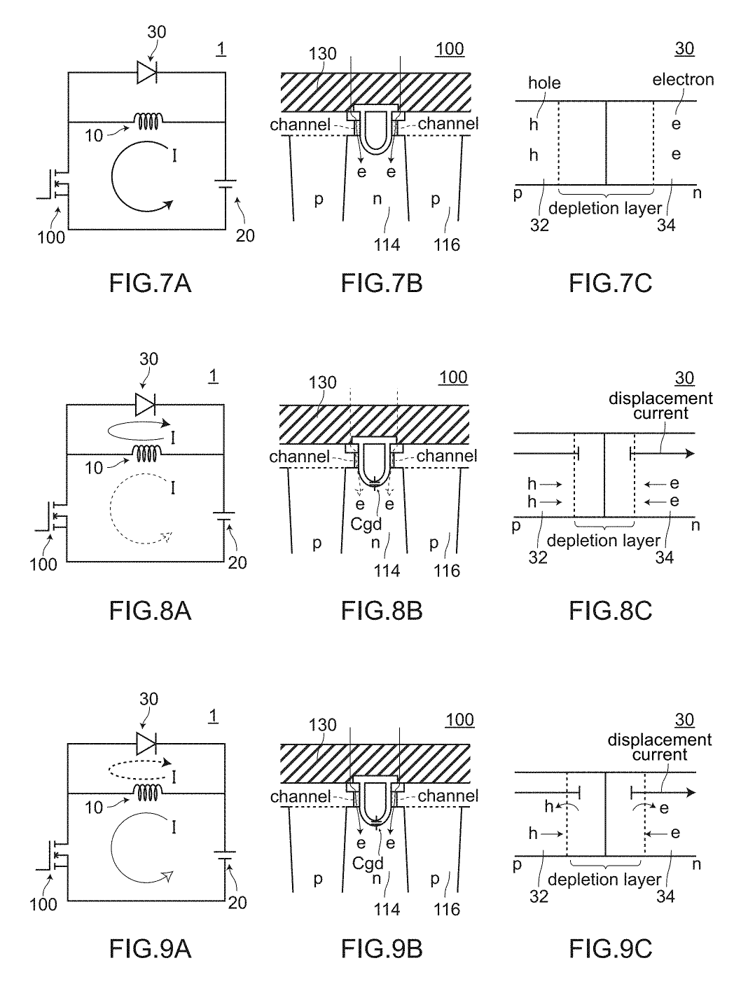

In such a power conversion circuit 1, when the MOSFET 100 is in an ON state, an electric current path from a positive pole (+) of the power source 20 to the negative pole (−) of the power source 20 through the reactor 10 and the MOSFET 100 is formed, and an electric current flows through the electric current path (see FIG. 7A). In this case, electric energy of the power source 20 is stored in the reactor 10.

When the MOSFET 100 is turned off, an electric current which flows through the electric current path from the positive pole (+) of the power source 20 to the negative pole (−) of the power source 20 through the reactor 10 and the MOSFET 100 is decreased and becomes 0 soon (see FIG. 11A). On the other hand, the reactor 10 generates an electromotive force in a direction in which a change in an electric current is obstructed (electric energy stored in the reactor 10 is discharged) due to a self induction effect. An electric current generated due to an electromotive force of the reactor 10 flows to the rectifier element 30, and a forward electric current flows in the rectifier element 30 (see FIG. 11A).

A sum of an amount of an electric current which flows through the MOSFET 100 and an amount of an electric current which flows through the rectifier element 30 is equal to an amount of an electric current which flows through the reactor 10. A switching period of the MOSFET 100 is short (possibly 100 nanoseconds at maximum) and hence, an amount of an electric current which flows through the reactor 10 minimally changes during such a period. Accordingly, a sum of an amount of an electric current which flows through the MOSFET 100 and an amount of an electric current which flows through the rectifier element 30 minimally changes in either case, that is, an ON state, a turn-off period or an OFF state.

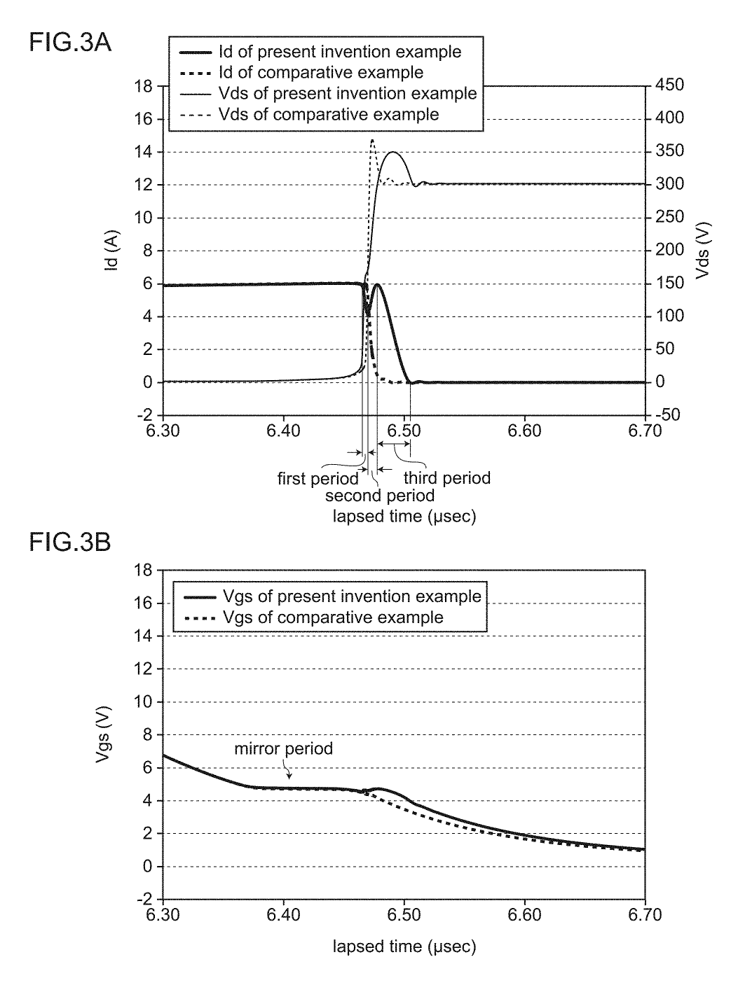

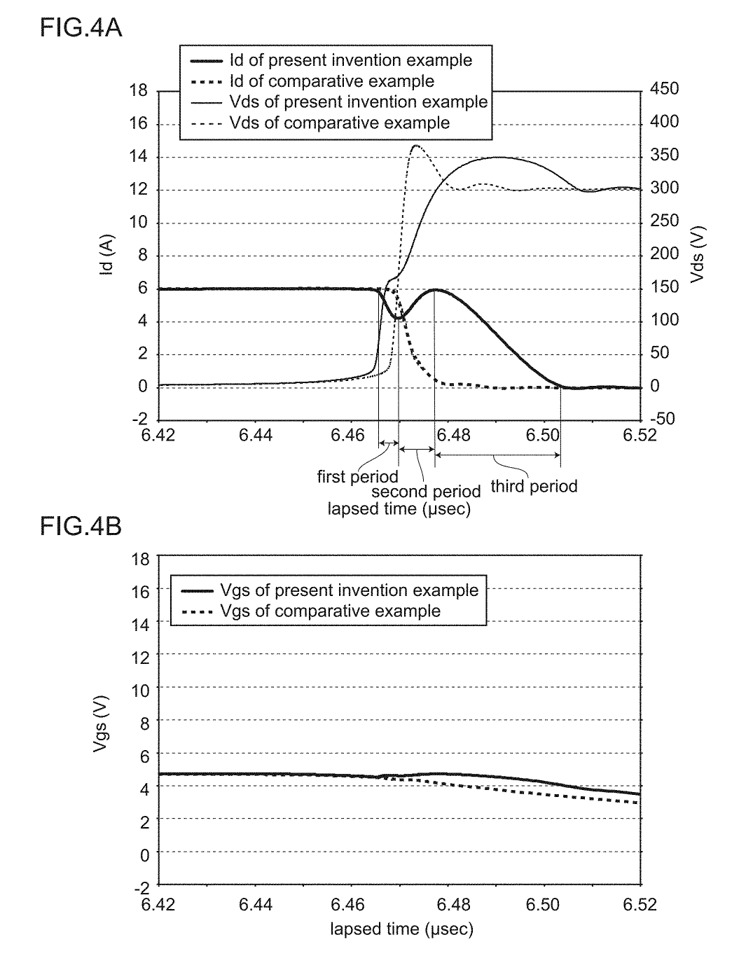

In such a power conversion circuit 1, assume a case where, as the MOSFET, a conventional MOSFET 900 or a MOSFET (a MOSFET according to Comparative example) where a total amount of a dopant in p-type column regions is set higher than a total amount of a dopant in n-type column regions is used. In such a case, when the MOSFET is turned off, a drain current Id of the MOSFET is sharply decreased and a drain-source voltage Vds is sharply increased and hence, a surge voltage is increased (see Vds of Comparative example shown in FIG. 3A and FIG. 4A).

Accordingly, in the present invention, as the MOSFET, the MOSFET 100 according to Embodiment 1 having the following structure is used.

### 2. Structure of MOSFET 100 According to Embodiment 1

As shown in FIG. 2, the MOSFET 100 according to Embodiment 1 is a trench-gate-type MOSFET which includes a semiconductor base substrate 110, a trench 122, a gate electrode 126, an interlayer insulation film 128, a source electrode 130, and a drain electrode 132. A drain-source withstand voltage of the MOSFET 100 is 300V or more, for example, 600V.

The semiconductor base substrate 110 has an n-type low-resistance semiconductor layer 112, an n-type buffer layer 113 formed on the low-resistance semiconductor layer 112 and having a lower dopant concentration than dopant concentration of the low-resistance semiconductor layer 112, n-type column regions 114 and p-type column regions 116 formed on the buffer layer 113 where the n-type column region 114 and the p-type column region 116 are alternately arranged along a horizontal direction, a p-type base region 118 formed on surfaces of the n-type column regions 114 and surfaces of the p-type column regions 116, and n-type source regions 120 formed on a surface of the base region 118, wherein the n-type column regions 114 and the p-type column regions 116 form a super junction structure. The buffer layer 113 and the n-type column regions 114 are integrally formed, and the buffer layer 113 and the n-type column region 114 form an n-type semiconductor layer 115.

In the semiconductor base substrate 110, the n-type column region 114 and the p-type column region 116 are formed such that a total amount of a dopant in the n-type column region 114 is higher than a total amount of a dopant in the p-type column region 116. To be more specific, a total amount of a dopant in the n-type column region 114 is set in a range of 1.05 times to 1.15 times as much as a total amount of a dopant in the p-type column region 116. For example, a total amount of a dopant in the n-type column region 114 is set to 1.10 times as much as a total amount of a dopant in the p-type column region 116.

In the p-type column region 116, in a depth direction of the p-type column region 116, a width of the p-type column region 116 is gradually increased as the p-type column region 116 extends from a deep portion of the p-type column region 116 toward a surface of the p-type column region 116. Dopant concentration in the p-type column region 116 is set to a fixed value regardless of a depth of the p-type column region 116.

All of the n-type column regions 114, the p-type column regions 116, the source regions 120, the trenches 122 and the gate electrodes 126 are formed in a stripe shape as viewed in a plan view.

A thickness of the low-resistance semiconductor layer 112 falls in a range of 100 μm to 400 μm and, for example, dopant concentration in the low-resistance semiconductor layer 112 falls in a range of 1×10¹⁹ cm⁻³ to 1×10²⁰ cm⁻³, for example. A thickness of the n-type semiconductor layer 115 falls in a range of 5 μm to 120 μm, for example. Dopant concentration in the n-type semiconductor layer 115 falls in a range of 5×10¹³ cm⁻³ to 1×10¹⁶ cm⁻³, for example. Dopant concentration of the p-type column region 116 falls in a range of 5×10¹³ cm⁻³ to 1×10¹⁶ cm⁻³, for example. A depth position of a deepest portion of the base region 118 falls in a range of 0.5 μm to 2.0 μm, for example, and dopant concentration of the base region 118 falls in a range of 5×10¹⁶ cm⁻³ to 1×10¹⁸ cm⁻³, for example. A depth position of a deepest portion of the source region 120 falls in a range of 0.1 μm to 0.4 μm, for example, and dopant concentration of the source region 120 falls in a range of 5×10¹⁹ cm⁻³ to 2×10²⁰ cm⁻³, for example.

The trench 122 is formed in a region where the n-type column region 114 is positioned as viewed in a plan view such that the trench 122 reaches a depth position deeper than the deepest portion of the base region 118 and a portion of the source region 120 is exposed on an inner peripheral surface of the trench 122. A depth of the trench 122 is 3 μm, for example.

The gate electrode 126 is embedded in the inside of the trench 122 by way of a gate insulation film 124 formed on the inner peripheral surface of the trench 122. The gate insulation film 124 is formed of a silicon dioxide film formed by a thermal oxidation method and the gate insulation film 124 has a thickness of 100 nm, for example. The gate electrode 126 is formed by a CVD method and an ion implantation method and is made of low-resistance polysilicon.

The interlayer insulation film 128 is formed so as to cover a portion of the source region 120, the gate insulation film 124 and the gate electrode 126. The interlayer insulation film 128 is formed by a CVD method and is formed of a PSG film having a thickness of 1000 nm, for example.

The source electrode 130 is formed so as to cover the base region 118, a portion of the source region 120, and the interlayer insulation film 128. The source electrode 130 is electrically connected with the source region 120. The drain electrode 132 is formed on a surface of the low-resistance semiconductor layer 112. The source electrode 130 is made of aluminum-based metal (Al—Cu-based alloy, for example) having a thickness of 4 μm formed by, for example, a sputtering method. The drain electrode 132 is formed of a multi-layered metal film such as a Ti—Ni—Au film. A total thickness of the multi-layered metal film is 0.5 μm, for example.

3. Waveform and Operation of MOSFET 100 when MOSFET 100 is Turned Off

To describe the MOSFET 100 according to Embodiment 1, a MOSFET according to Comparative example is described first.

The MOSFET according to Comparative example basically has the structure which is substantially same to the structure of the MOSFET 100 according to Embodiment 1. However, the MOSFET according to the Comparative example differs from the MOSFET 100 according to Embodiment 1 with respect to a total amount of a dopant in an n-type column region and a total amount of a dopant in a p-type column region. That is, in the MOSFET according to Comparative example, a total amount of a dopant in the p-type column region is set to 1.10 times as much as a total amount of a dopant in the n-type column region.

In the power conversion circuit 1 according to Embodiment 1, when the MOSFET according to Comparative example is used in place of the MOSFET 100, the MOSFET according to Comparative example is operated such that a drain current Id is sharply decreased when the MOSFET is turned off (see a dotted line in FIG. 3A and FIG. 4A). Further, the MOSFET according to Comparative example is operated such that a drain-source voltage Vds sharply rises and reaches approximately 370V within a short period and, thereafter, oscillates and becomes stable at a power source voltage (300V). The MOSFET according to Comparative example is operated such that a gate-source voltage Vgs is monotonously decreased after a mirror period is finished (see a dotted line in FIG. 3B and FIG. 4B).

On the other hand, in the power conversion circuit 1 according to Embodiment 1 which uses the MOSFET 100 according to Embodiment 1, the MOSFET 100 is operated during a period from a point of time when a drain current Id starts to decrease to a point of time when the drain current Id becomes 0 for the first time, in response to turning off of the MOSFET such that a first period during which the drain current Id decreases, a second period during which the drain current Id increases, and a third period during which the drain current Id decreases again appear in this order (see a solid line in FIG. 3A and FIG. 4A). The MOSFET 100 is operated such that a gradient of a drain-source voltage Vds is decreased during the second period and, thereafter, the drain-source voltage Vds is gradually increased and reaches approximately 350V during the third period with a gradient smaller than a gradient during the first period, and the drain-source voltage Vds oscillates with amplitude smaller than amplitude of oscillation in the MOSFET according to Comparative example and becomes stable at a power source voltage (300V). The MOSFET 100 is operated such that a period during which a gate-source voltage Vgs is temporarily increased appears after a mirror period is finished (see a solid line in FIG. 3B and FIG. 4B).

A decrease amount of a drain current Id per unit time during the third period is set smaller than a decrease amount of a drain current Id per unit time during the first period (see FIG. 3A and FIG. 4A).

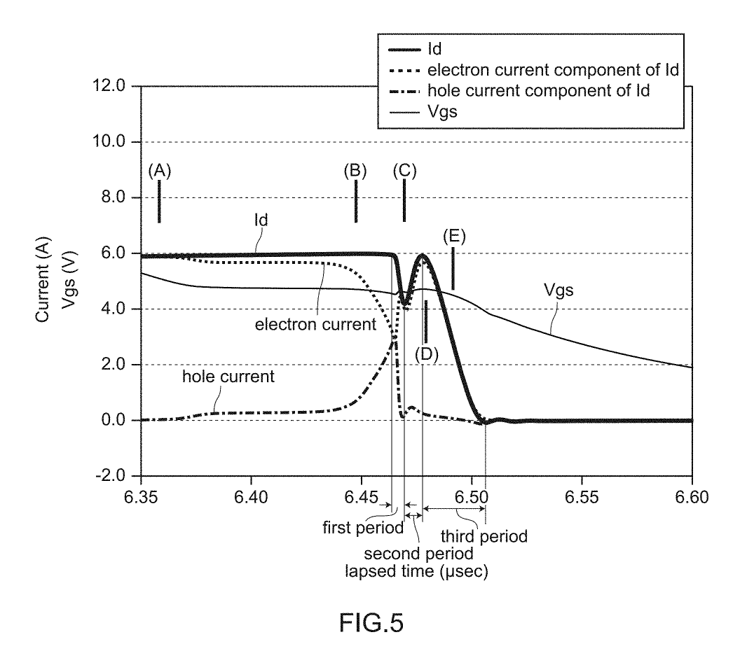

In the MOSFET 100, during the last period of the mirror period (see symbol (B) in FIG. 5), an electron current component of a drain current Id is decreased and, at the same time, a hole current component of the drain current Id is increased. Then, the hole current component disappears and hence, the drain current Id starts to decrease (first period). However, an electron current component is temporarily increased so that the drain current Id is increased (second period). Then, along with the decrease of the electron current component, the drain current Id is also decreased and becomes 0 (third period).

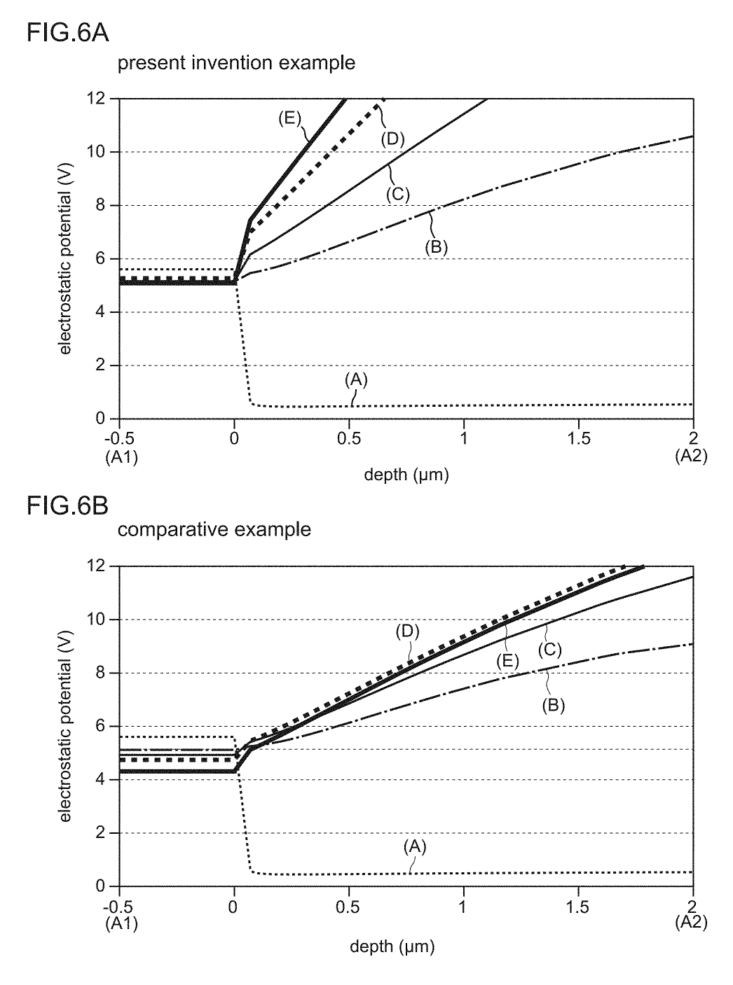

In the MOSFET according to Comparative example, when the MOSFET is turned off, an electrostatic potential of the n-type column region around the gate (for example, an electrostatic potential at a position where a depth from a depth position of a lowermost portion of the gate electrode 126 (an interface between the gate electrode 126 and the gate insulation film 124) is 0.5 μm) is increased to approximately 6V at the last period of a mirror period (see symbol (B) in FIG. 6B) from less than 0.5V during the mirror period (see symbol (A) in FIG. 6B). However, thereafter, even when a time elapses (even when a drain potential is increased) during a turn-off period, the electrostatic potential is increased only to approximately 7V (see symbols (C), (D) and (E) in FIG. 6B).

On the other hand, in the MOSFET of the present invention example, when the MOSFET is turned off, an electrostatic potential of the n-type column region around the gate (for example, an electrostatic potential at a position where a depth from a depth position of a lowermost portion of the gate electrode 126 (an interface between the gate electrode 126 and the gate insulation film 124) is 0.5 μm) is increased to approximately 6V at the last period of a mirror period (see symbol (B) in FIG. 6A) from less than 0.5V during the mirror period (see symbol (A) in FIG. 6A). Even after such a period, the electrostatic potential is increased to approximately 8.5V at the last period of the first period (see symbol (C) in FIG. 6A), and is increased to approximately 10.5V during the last period of the second period (see symbol (D) in FIG. 6A).

In this manner, when the MOSFET is turned off, an electrostatic potential of the n-type column region around the gate is increased and hence, a potential of the gate electrode 126 is increased via a gate-drain capacitance Cgd whereby a gate-source voltage Vgs is increased. As a result, a channel expands again so that the second period during which a drain current is increased appears.

### 4. Operations of Power Conversion Circuit 1, MOSFET 100 and Rectifier Element 30

### (1) ON State

When the MOSFET 100 is in an ON state, in the power conversion circuit 1, the electric current path from a positive pole (+) of the power source 20 to a negative pole (−) of the power source 20, through the reactor 10 and the MOSFET 100, is formed (see FIG. 7A). In this case, electric energy of the power source 20 is stored in the reactor 10.

In the MOSFET 100, a channel is formed in the base region 118 so as to electrically interconnect the drain electrode 132 and the source electrode 130 (see FIG. 7B).

In the rectifier element 30, an electric current does not flow in the rectifier element 30, and a depletion layer, formed by a PN junction surface between a p-type region 32 of an anode electrode side and an n-type region 34 of a cathode electrode side, expands (see FIG. 7C).

### (2) Turn-Off Period

In the power conversion circuit 1, an electric current, which flows through the electric current path from a positive pole (+) of the power source 20 to a negative pole (−) of the power source 20 via the reactor 10 and the MOSFET 100, is decreased (see FIG. 8A) and becomes 0 soon. On the other hand, the reactor 10 generates an electromotive force for maintaining an electric current which flows through the reactor 10. The generated electromotive force changes a reverse bias applied to the rectifier element 30 to a forward bias so that a forward electric current flows in the rectifier element 30.

### (2-1) First Period

In the MOSFET 100, a gate potential is largely lowered, and a channel formed in the base region 118 becomes narrow (see FIG. 8B). Accordingly, electrons hardly flow from the source electrode 130 into the semiconductor base substrate 110 so that a drain current Id is lowered.

In the rectifier element 30, a reverse bias is decreased so that carriers are moved toward the depletion layer which expands from the PN junction surface (holes going toward the depletion layer from the p-type region 32 and electrons going toward the depletion layer from the n-type region 34). Accordingly, the depletion layer is gradually narrowed and, at the same time, a displacement current flows in the rectifier element 30 (see FIG. 8C).

During the first period, a drain potential is increased along with a lapse of time, and a potential (electrostatic potential) of the n-type column region 114 around the gate is also increased along with a lapse of time. Then, a lowered potential of the gate electrode 126 is increased via a gate-drain capacitance Cgd, and the channel is expanded so that a drain current Id is increased, and the MOSFET 100 is shifted to the second period.

### (2-2) Second Period

In the power conversion circuit 1, an electric current which flows through the electric current path from the positive pole (+) of the power source 20 to the negative pole (−) of the power source 20 through the reactor 10 and the MOSFET 100 is temporarily increased. On the other hand, an electric current which flows from the reactor 10 to the rectifier element 30 from the reactor 10 is temporarily decreased (see FIG. 9A).

In the MOSFET 100, a potential of the gate electrode is increased and, eventually, a gate-source voltage Vgs is increased so that the channel of the base region 118 is temporarily expanded (see FIG. 9B). Accordingly, electrons which flow from the source electrode 130 into the semiconductor base structure 110 so that an electric current which flows in the source electrode 130 from the drain electrode 132 is temporarily increased.

In the rectifier element 30, some holes h move from the depletion layer toward an anode electrode side and, at the same time, some electrons e move from the depletion layer toward a cathode electrode side. Accordingly, the depletion layer is expanded compared to the first period. Accordingly, an electric current component which flows backward in the rectifier element 30 is generated and hence, an amount of electric current which flows through the rectifier element 30 is decreased (see FIG. 9C).

### (2-3) Third Period

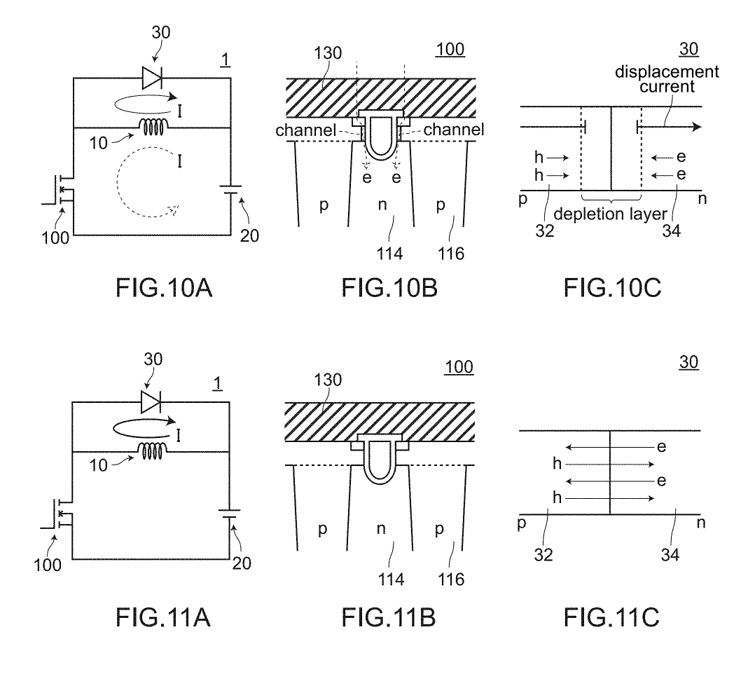

In the power conversion circuit 1, an electric current, which flows through the electric current path from the positive pole (+) of the power source 20 to the negative pole (−) of the power source 20 via the reactor 10 and the MOSFET 100, is decreased (see FIG. 10A). On the other hand, the reactor 10 generates an electromotive force for maintaining an electric current which flows through the reactor 10. The generated electromotive force decreases a reverse bias applied to the rectifier element 30.

In the MOSFET 100, a gate-source voltage Vgs starts to decrease again and, in the same manner as the first period, a channel formed in the base region 118 is narrowed so that an electric current which flows between the drain electrode 132 and the source electrode 130 is decreased (see FIG. 10B). Then, when the gate-source voltage Vgs becomes less than a gate threshold value voltage, the channel disappears so that a drain current Id becomes 0 (OFF state).

In the rectifier element 30, the depletion layer is narrowed again and, at the same time, a displacement current flows in the rectifier element 30 (see FIG. 10C).

### (3) OFF State

In the power conversion circuit 1, an electric current, which flows through the electric current path from the positive pole (+) of the power source 20 to the negative pole (−) of the power source 20 via the reactor 10 and the MOSFET 100, becomes 0 (see FIG. 11A). On the other hand, an electric current, having the same current amount as an electric current which flows in the MOSFET in an ON state, flows in the rectifier element 30.

In the MOSFET 100, a gate-source voltage Vgs becomes less than a gate threshold voltage and hence, the channel disappears and a drain current Id becomes 0 (see FIG. 11B).

In the rectifier element 30, the depletion layer which expands from the PN junction surface disappears, and electrons and holes directly flow in the rectifier element 30 respectively (see FIG. 11C).

Even when a silicon-carbide Schottky barrier diode (SiC-SBD) is used as the rectifier element, an operation of the MOSFET 100 during a turn-off period is almost the same to that in the case where a silicon fast recovery diode (Si-FRD) is used as the rectifier element (the case of the power conversion circuit 1 according to the above-mentioned Embodiment 1), and the periods from the first period to the third period appear during the turn-off period.

The reason is as follows. That is, if a SiC-SBD is used as the rectifier element, when a reverse bias is applied, a depletion layer in a semiconductor is used as a dielectric, a capacitance is generated between a Schottky electrode and a portion of a semiconductor base substrate which is not depleted, and a Schottky junction portion has a junction capacitance (this junction capacitance is possibly equal to or larger than a corresponding junction capacitance in the case where an Si-FRD is used as the rectifier element). Accordingly, even when a SiC-SBD is used as the rectifier element, a displacement current flows due to a change in a bias voltage.

Accordingly, in the above-mentioned description of the operation of the rectifier element where an Si-FRD is used as the rectifier element (the case of the power conversion circuit 1 according to the above-mentioned Embodiment 1), an operation mechanism where a SiC-SBD is used as the rectifier element is directly applicable, by replacing a capacitance of a PN junction with a capacitance of a Schottky junction, as an operation mechanism including a behavior of a displacement current. As a result, even when a SiC-SBD is used as the rectifier element, an operation of the MOSFET 100 during a turn-off period is almost the same to that in the case where a Si-FRD is used as the rectifier element (the case of the power conversion circuit according to the above-mentioned Embodiment 1), and the periods from the first period to the third period appear during the turn-off period.

### 5. Advantageous Effect Acquired by MOSFET 100 and Power Conversion Circuit 1 According to Embodiment 1

According to the MOSFET 100 and the power conversion circuit 1 according to Embodiment 1, the n-type column region 114 and the p-type column region 116 are formed such that a total amount of a dopant in the n-type column region 114 is set higher than a total amount of a dopant in the p-type column region 116, and the MOSFET 100 is configured to be operated during a period from a point of time when a drain current Id starts to decrease to a point of time when the drain current Id becomes 0 for the first time in response to turning off of the MOSFET 100 such that the first period during which the drain current Id decreases, the second period during which the drain current increases, and the third period during which the drain current decreases again appear in this order. Accordingly, compared to the conventional MOSFET 900, a time until a current value of a drain current Id becomes 0 can be extended and, at the same time, a decrease amount of a drain current Id per unit time during the third period can be made small (see a solid line in FIG. 3A and FIG. 4A). Accordingly, a surge voltage of the MOSFET can be made smaller than a surge voltage of the conventional MOSFET 900 and hence, the MOSFET 100 and the power conversion circuit 1 according to Embodiment 1 can easily satisfy a standard for a surge voltage which the power conversion circuit is required to possess. As a result, the MOSFET 100 and the power conversion circuit 1 according to Embodiment 1 are applicable to various power conversion circuits.

According to the MOSFET 100 and the power conversion circuit 1 of Embodiment 1, as described above, compared to the conventional MOSFET 900, the time until a drain-source voltage Vds becomes maximum can be extended and, at the same time, an increment per unit time of the drain-source voltage Vds until the drain-source voltage Vds becomes maximum can be made small and hence, oscillation minimally occurs compared to the conventional MOSFET 900.

Oscillation in the circuit is a “ringing” phenomenon where an electric current and a voltage wave after the electric current becomes 0 for the first time when a surge voltage is high. Accordingly, the increase or decrease of an electric current during a period ranging from the first period to the third period of the present invention does not correspond to oscillation.

The MOSFET 100 of Embodiment 1 includes the semiconductor base substrate 110 where the super junction structure is formed of the n-type column regions 114 and the p-type column regions 116. Accordingly, in the same manner as the conventional MOSFET 900, the MOSFET 100 is a switching element having a low ON resistance and a high withstand voltage.

Further, according to the MOSFET 100 of Embodiment 1, a total amount of a dopant in the n-type column region is set in a range of 1.05 times to 1.15 times as much as a total amount of a dopant in the p-type column region. Accordingly, when the MOSFET 100 is turned off, the n-type column region 114 around the gate is minimally depleted. Accordingly, along with the increase of a drain potential, a potential of the n-type column region 114 around the gate is easily increased. As a result, a potential of the gate electrode 126 is easily increased via a gate-drain capacitance Cgd and hence, the second period, during which a drain current Id is increased during a period from a point of time when the drain current Id starts to decrease to a point of time when the drain current Id becomes 0 for the first time, easily appears and, at the same time, a drain-source withstand voltage can be increased.

A total amount of a dopant in the n-type column region is set in a range of 1.05 times to 1.15 times as much as a total amount of a dopant in the p-type column region due to the following reason. In the case where a total amount of a dopant in the n-type column region 114 is set to less than 1.05 times as much as a total amount of a dopant in the p-type column region 116, when the MOSFET is turned off, the n-type column region 114 around the gate is easily depleted. Accordingly, an electrostatic potential in such a region is minimally increased and a gate-drain capacitance Cgd is decreased and hence, it is difficult to increase a gate potential. In the case where a total amount of a dopant in the n-type column region 114 becomes more than 1.15 times as much as a total amount of a dopant in the p-type column region 116, when the MOSFET is turned off, it is difficult to increase a drain-source withstand voltage of the MOSFET and hence, the second period hardly appears. From these points of view, it is preferable that a total amount of a dopant in the n-type column region be set in a range of 1.05 times to 1.12 times as much as a total amount of a dopant in the p-type column region.

According to the MOSFET 100 of Embodiment 1, a decrease amount of a drain current Id per unit time during the third period is smaller than a decrease amount of a drain current Id per unit time during the first period and hence, a surge voltage of the MOSFET 100 can be made further small when the MOSFET 100 is turned off. As a result, the MOSFET 100 according to Embodiment 1 can easily satisfy a standard for a surge voltage which the power conversion circuit is required to possess with more certainty and hence, the MOSFET 100 according to Embodiment 1 is applicable to further various power conversion circuits.

According to the MOSFET 100 of Embodiment 1, the MOSFET 100 is operated such that, in response to turning off of the MOSFET 100, a gate-source voltage Vgs is temporarily increased after a mirror period is finished and hence, compared to the conventional MOSFET 900, a time until a current value of a drain current Id becomes 0 can be extended with certainty and, at the same time, a decrease amount of a drain current Id per unit time during the third period can be made small with certainty. Accordingly, a surge voltage of the MOSFET 100 can be made small with certainty and hence, the MOSFET 100 according to Embodiment 1 can easily satisfy a standard for a surge voltage which the power conversion circuit is required to possess with more certainty and the MOSFET 100 according to Embodiment 1 is applicable to various power conversion circuits.

According to the MOSFET 100 of Embodiment 1, the MOSFET 100 is a trench-gate-type MOSFET which includes: the trench 122 which is formed so as to reach a depth position deeper than a deepest portion of the base region 118 in a region where the n-type column region 114 is positioned as viewed in a plan view; and the gate electrode 126 embedded in the inside of the trench 122 by way of the gate insulation film 124 formed on the inner peripheral surface of the trench 122. Accordingly, (1) at a lower portion of the gate electrode 126, a side surface side and a bottom portion side of the gate electrode 126 are surrounded by the n-type column region 114 and hence, when the MOSFET 100 is turned off and a potential of the n-type column region 114 is increased, a gate potential is easily increased via a gate-drain capacitance Cgd. Further, (2) compared to a case of a planar-gate-type MOSFET, the gate electrode and the drain electrode are disposed close to each other and hence, a potential of the n-type column region 114 around the gate is easily increased. Accordingly, a surge voltage of the MOSFET 100 can be made further small. As a result, the MOSFET 100 of Embodiment 1 can more easily satisfy a standard for a surge voltage which the power conversion circuit 1 is required to possess so that the MOSFET 100 of Embodiment 1 is applicable to further various power conversion circuits.

According to the MOSFET 100 of Embodiment 1, in the p-type column region 116, in a depth direction of the p-type column region 116, a width of the p-type column region 116 is increased as the p-type column region 116 extends from a deep portion of the p-type column region 116 toward a surface of the p-type column region 116 and hence, when the MOSFET is turned off, holes around the gate can be easily extracted. As a result, an L-load avalanche breakdown resistance can be increased.

According to the power conversion circuit 1 of Embodiment 1, the rectifier element 30 is a fast recovery diode and hence, when the MOSFET 100 is turned on, a loss caused by a reverse recovery current can be decreased.

### [Modification]

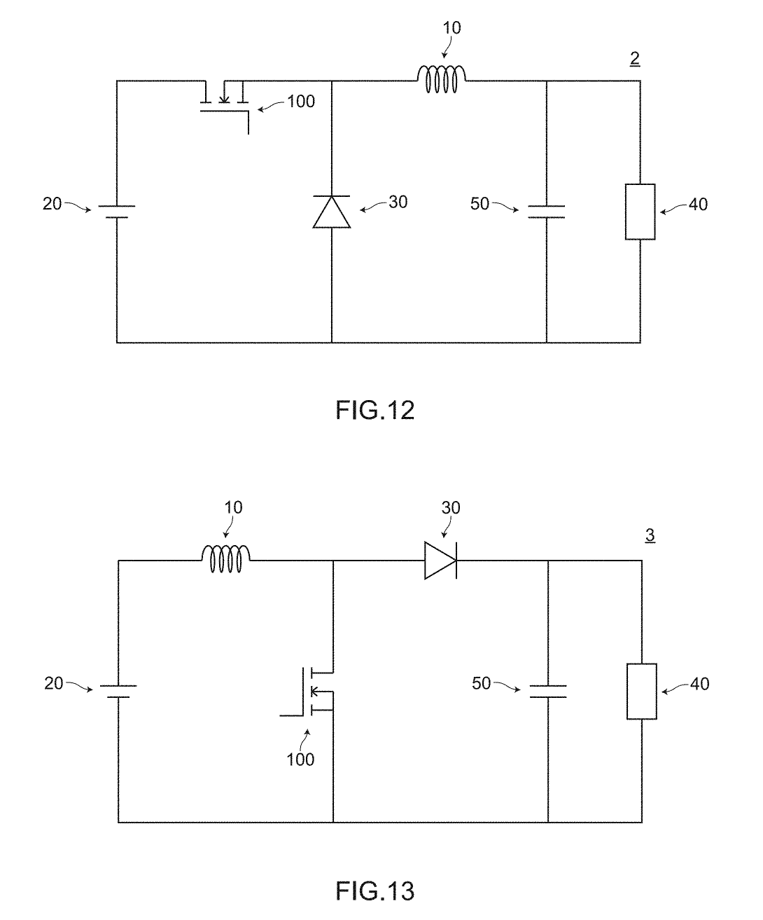

A power conversion circuit 2 according to Modification 1 and a power conversion circuit 3 according to Modification 2 basically have the structures substantially same to those of the power conversion circuit 1 according to Embodiment 1. However, the power conversion circuit 2 according to Modification 1 and the power conversion circuit 3 according to Modification 2 differ from the power conversion circuit 1 according to Embodiment 1 with respect to positional relationships of the respective constitutional elements. That is, the power conversion circuit 2 according to Modification 1 is a step-down chopper circuit as shown in FIG. 12, and the power conversion circuit 3 according to Modification 2 is a step-up chopper circuit as shown in FIG. 13.

In this manner, the power conversion circuit 2 according to Modification 1 and the power conversion circuit 3 according to Modification 2 differ from the power conversion circuit 1 according to Embodiment 1 with respect to the positional relationships of the respective constitutional elements. However, in the same manner as the power conversion circuit 1 according to Embodiment 1, the power conversion circuit 2 according to Modification 1 and the power conversion circuit 3 according to Modification 2 are configured such that n-type column regions 114 and p-type column regions 116 are formed such that a total amount of a dopant in the n-type column region 114 is set higher than a total amount of a dopant in the p-type column region 116, and the MOSFET 100 is configured to be operated during a period from a point of time when a drain current Id starts to decrease to a point of time when the drain current Id becomes 0 for the first time in response to turning off of the MOSFET 100 such that a first period during which the drain current Id decreases, a second period during which the drain current Id increases, and a third period during which the drain current Id decreases again appear in this order. Accordingly, a time until a current value of a drain current Id becomes 0 can be relatively extended and, at the same time, a decrease amount of a drain current Id per unit time during the third period can be made relatively small (see a solid line in FIG. 3A and FIG. 4A). Accordingly, a surge voltage of the MOSFET can be made relatively small and hence, the power conversion circuit 2 according to Modification 1 and the power conversion circuit 3 according to Modification 2 can easily satisfy a standard for a surge voltage which the power conversion circuit is required to possess. As a result, the power conversion circuit 2 according to Modification 1 and the power conversion circuit 3 according to Modification 2 are applicable to various power conversion circuits.

### Embodiment 2

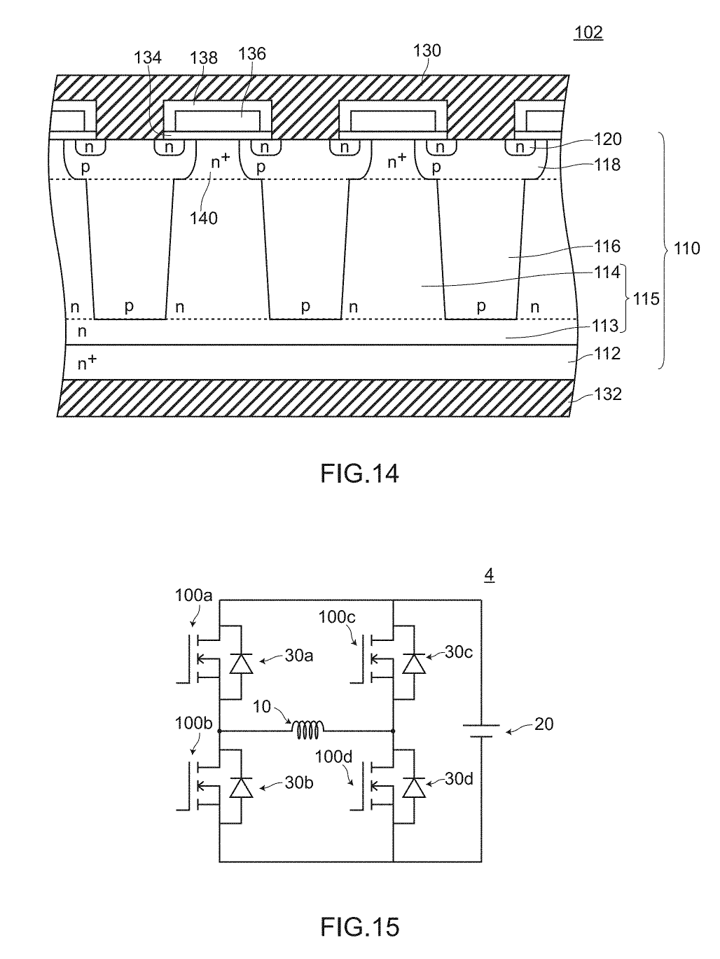

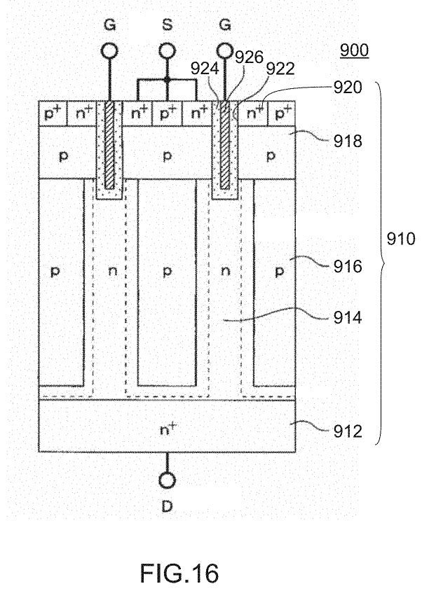

A MOSFET 102 according to Embodiment 2 basically has the structure substantially same to the structure of the MOSFET 100 according to Embodiment 1. However, the MOSFET 102 according to Embodiment 2 differs from the MOSFET 100 according to Embodiment 1 with respect to a point where the MOSFET 102 according to Embodiment 2 is not a trench-gate-type MOSFET but is a planar-gate-type MOSFET. That is, in the MOSFET 102 according to Embodiment 2, as shown in FIG. 14, the semiconductor base substrate 110 further includes: a p-type base region 118 formed on surfaces of portions of n-type column regions 114 and whole surfaces of p-type column regions 116; and n-type source regions 120 formed on a surface of the base region 118, and the MOSFET 102 according to Embodiment 2 is a planar-gate-type MOSFET which further includes a gate electrode 136 which are formed on the base region 118 and the gate electrode is sandwiched between the source region 120 and the n-type column region 114 by way of a gate insulation film 134.

In the MOSFET 102 according to Embodiment 2, the semiconductor base substrate 110 further includes n-type surface high concentration diffusion regions 140 each of which is formed on a portion of the surface of the n-type column region 114 where the base region 118 is not formed. Dopant concentration in the surface high concentration diffusion region 140 is set higher than dopant concentration in the n-type column region 114.

As described above, the MOSFET 102 according to Embodiment 2 differs from the MOSFET 100 according to Embodiment 1 with respect to the point where the MOSFET 102 according to Embodiment 2 is not a trench-gate-type MOSFET but is a planar-gate-type MOSFET. However, in the same manner as the MOSFET 100 according to Embodiment 1, the n-type column region 114 and the p-type column region 116 are formed such that a total amount of a dopant in the n-type column region 114 is set higher than a total amount of a dopant in the p-type column region 116, and the MOSFET 100 is configured to be operated during a period from a point of time when a drain current Id starts to decrease to a point of time when the drain current Id becomes 0 for the first time in response to turning off of the MOSFET 100 such that a first period during which the drain current Id decreases, a second period during which the drain current Id increases, and a third period during which the drain current Id decreases again appear in this order. Accordingly, compared to the conventional MOSFET 900, a time until a current value of a drain current Id becomes 0 can be extended and, at the same time, a decrease amount of a drain current Id per unit time during the third period can be made small (see a solid line in FIG. 3A and FIG. 4A). Accordingly, a surge voltage of the MOSFET can be made smaller than a surge voltage of the conventional MOSFET 900 and hence, the MOSFET 102 according to Embodiment 2 can easily satisfy a standard for a surge voltage which the power conversion circuit is required to possess. As a result, the MOSFET 102 according to Embodiment 2 is applicable to various power conversion circuits.

According to the MOSFET 102 of Embodiment 2, the semiconductor base substrate 110 has the n-type surface high concentration diffusion region 140 which is formed on a portion of the surface of the n-type column region 114 where the base region 118 is not formed and hence, when the MOSFET is turned off, the surface high concentration diffusion region 140 is minimally depleted whereby along with the increase of a drain potential, a potential of the n-type column region 114 around the gate is easily increased. Accordingly, a potential of the gate electrode 136 is easily increased via a gate-drain capacitance Cgd. As a result, the second period during which a drain current Id is increased easily appears during a period from a point of time when the drain current Id starts to decrease to a point of time when the drain current Id becomes 0 for the first time.

The MOSFET 102 according to Embodiment 2 has the structure substantially same to the structure of the MOSFET 100 according to Embodiment 1 with respect to points other than the point where the MOSFET 102 according to Embodiment 2 is not a trench-gate-type MOSFET but is a planar-gate-type MOSFET and hence, the MOSFET 102 according to Embodiment 2 acquires advantageous effects corresponding to the advantageous effects which the MOSFET 102 according to Embodiment 2, among advantageous effects which the MOSFET 100 according to Embodiment 1, possesses.

### Embodiment 3

A power conversion circuit 4 according to Embodiment 3 basically has the structure substantially same to the structure of the power conversion circuit 1 according to Embodiment 1. However, the power conversion circuit 4 according to Embodiment 3 differs from the MOSFET 100 according to Embodiment 1 with respect to a point where the power conversion circuit is a full bridge circuit. That is, as shown in FIG. 15, the power conversion circuit 4 according to Embodiment 3 includes four MOSFETs 100 as the MOSFET, and also includes built-in diodes of the respective MOSFETs as rectifier elements.

As described above, the power conversion circuit 4 according to Embodiment 3 differs from the power conversion circuit 1 according to Embodiment 1 with respect to the point where the power conversion circuit is a full bridge circuit. However, in the same manner as the power conversion circuit 1 according to Embodiment 1, n-type column region 114 and p-type column region 116 are formed such that a total amount of a dopant in the n-type column region 114 is set higher than a total amount of a dopant in the p-type column region 116, and the MOSFET 100 is configured to be operated during a period from a point of time when a drain current Id starts to decrease to a point of time when the drain current Id becomes 0 for the first time in response to turning off of the MOSFET 100 such that a first period during which the drain current Id decreases, a second period during which the drain current Id increases, and a third period during which the drain current Id decreases again appear in this order. Accordingly, compared to the conventional MOSFET 900, a time until a current value of a drain current Id becomes 0 can be extended and, at the same time, a decrease amount of a drain current Id per unit time during the third period can be made small (see a solid line in FIG. 3A and FIG. 4A). Accordingly, a surge voltage of the MOSFET can be made smaller than a surge voltage of the conventional MOSFET 900 and hence, the power conversion circuit 4 according to Embodiment 3 can easily satisfy a standard for a surge voltage which the power conversion circuit is required to possess. As a result, the power conversion circuit 4 according to Embodiment 3 is applicable to various power conversion circuits.

Further, according to the power conversion circuit 4 of Embodiment 3, the rectifier element is the built-in diode of the MOSFET and hence, it is unnecessary to prepare a rectifier element as an additional part.

The power conversion circuit 4 according to Embodiment 3 has the structure substantially same to the structure of the power conversion circuit 1 according to Embodiment 1 with respect to points other than the point where the power conversion circuit is a full bridge circuit. Accordingly, the power conversion circuit 4 according to Embodiment 3 acquires advantageous effects corresponding to the advantageous effects which the power conversion circuit 4 according to Embodiment 3, among advantageous effects which the power conversion circuit 1 according to Embodiment 1, possesses.

In a full bridge circuit, there may be a case where a phenomenon referred to as “false turn-on” occurs whereby a circuit loss is increased. This operation mechanism is described hereinafter.

In FIG. 15, assume a state where both a MOSFET 100a and a MOSFET 100b are in OFF states, and an electric current flows through a reactor 10 from left to right.

An electric current which flows in the reactor 10 from left flows through a rectifier element 30b from below to above.

Next, when the MOSFET 100a is turned on, a source potential of the MOSFET 100a is rapidly increased, and a drain potential of the MOSFET 100b is also rapidly increased simultaneously with the rapid increase of the source potential of the MOSFET 100a. At this stage of operation, when a gate potential of the MOSFET 100b is pulled toward a drain potential, a plus bias is effectively applied between a gate and a source of the MOSFET 100b and hence, the MOSFET 100b is erroneously turned on. As a result, a state is brought about where the MOSFET 100a and the MOSFET 100b are simultaneously turned on. When the MOSFETs of upper and lower arms are simultaneously turned on, a short-circuit loop is formed from a positive pole to a negative pole of the power source 20 and hence, a through-current flows so that a circuit loss is increased.

As an another example, assume a state where both the MOSFET 100a and the MOSFET 100b are in OFF states, and an electric current flows in the reactor 10 from right to left. An electric current which flows out leftward from the reactor 10 flows through a rectifier element 30a from below to above.

Next, when the MOSFET 100b is turned on, a drain potential of the MOSFET 100b is rapidly lowered, and a source potential of the MOSFET 100a is also rapidly lowered simultaneously with the rapid lowering of the drain potential of the MOSFET 100b.

At this stage, in the case where a gate potential of the MOSFET 100a is not simultaneously lowered with a source potential, a plus bias is effectively applied between a gate electrode and a source electrode of the MOSFET 100a and hence, the MOSFET 100a is erroneously turned on. Also in this case, a state is brought about where the MOSFET 100a and the MOSFET 100b are simultaneously turned on.

The above describes a phenomenon referred to as “false turn-on”. That is, “false turn-on” is a phenomenon where, in a circuit where MOSFETs are connected to upper and lower arms respectively, when either one of the MOSFETs is turned on, the other MOSFET is also erroneously turned on due to a change in electrostatic potential.

In the operation mechanism according to the present invention, when the MOSFET is turned off, the MOSFET is temporarily and spontaneously brought into a state where the MOSFET is almost turned on. That is, this state is an effect acquired at the time of turning off the MOSFET. Accordingly, this state, in principle, differs from “false turn-on” which occurs when the MOSFET is turned on.

Accordingly, in the present invention, there is no possibility that a through-current flows so that a circuit loss is increased.

In the chopper circuits described in Embodiment 1, Modification 1, and Modification 2 (see FIG. 1, FIG. 12 and FIG. 13), there may be a case where a rectifying function of the rectifier element 30 is exchanged with a built-in diode of a MOSFET different from the MOSFET 100, for introducing a synchronous rectification. In this case, two MOSFETs are connected in series thus giving rise to a possibility that “false turn-on” occurs.

However, also in this case, “false turn-on” occurs in response to turning on of either one of two MOSFETs and hence, this phenomenon also, in principle, differs from an effect obtained at the time of turning off the MOSFET in the present invention.

Although the present invention has been described based on the above-mentioned embodiments, the present invention is not limited to the above-mentioned embodiments. The present invention can be carried out in various modes without departing from the gist of the present invention, and, for example, the following modifications are also possible.

(1) The number, materials, shapes, positions, sizes and the like of the constitutional elements described in the above-mentioned embodiments are provided for an exemplifying purpose, and these matters can be changed in various modes within a scope where advantageous effects of the present invention are not impaired.
(2) In the above-mentioned respective embodiments, in a depth direction of the p-type column region 116, a width of the p-type column region 116 is increased as the p-type column region 116 extends from a deep portion of the p-type column region 116 toward a surface of the p-type column region 116. However, the present invention is not limited to such a structure. The width of the p-type column region 116 may be set to a fixed value in the depth direction of the p-type column region 116.
(3) In the above-mentioned respective embodiments, dopant concentration in the p-type column region 116 is set to a fixed value regardless of a depth of the p-type column region 116. However, the present invention is not limited to such a structure. In a depth direction of the p-type column region 116, dopant concentration of the p-type column region may be gradually increased as the p-type column region 116 extends from a deep portion of the p-type column region 116 toward a surface of the p-type column region 116. With such a structure, it is possible to acquire an advantageous effect that an L-load avalanche breakdown resistance can be increased.
(4) In the above-mentioned respective embodiments, the n-type column regions 114, the p-type column regions 116, the trenches 122, and the gate electrodes 126 are formed in a stripe shape as viewed in a plan view. However, the present invention is not limited to such a structure. The n-type column regions 114, the p-type column regions 116, the trenches 122, and the gate electrodes 126 may be formed in a circular shape (in a columnar shape as viewed stereoscopically), a quadrangular frame shape, a circular frame shape, a circular grid shape or the like as viewed in a plan view.
(5) In the above-mentioned respective embodiments, a DC power source is used as the power source. However, the present invention is not limited to such a structure. An AC power source may be also used as the power source.
(6) A chopper circuit is used as the power conversion circuit in the above-mentioned respective Embodiments 1 to 3, and a full bridge circuit is used as the power conversion circuit in the above-mentioned Embodiment 4. However, the present invention is not limited to such structures. As the power conversion circuit, a half bridge circuit, a three-phase AC converter, a non-insulation-type full bridge circuit, a non-insulation-type half bridge circuit, a push-pull circuit, an RCC circuit, a forward converter, a fly-back converter or other circuits may be used.
(7) A PIN diode is used as the rectifier element in the above-mentioned Embodiments 1 and 2, and a built-in diode of the MOSFET is used as the rectifier element in the above-mentioned Embodiment 3. However, the present invention is not limited to such structures. As the rectifier element, a JBS, a MPS, or other fast recovery diodes, a SiC Schottky barrier diode or other diodes may be used.
(8) In the above-mentioned Embodiment 3, only a built-in diode of the MOSFET is used as the rectifier element. However, the present invention is not limited to such a structure. When a recovery loss of the built-in diode is excessively large, a rectifier element provided as an additional part may be connected to the MOSFET in parallel.

1. A MOSFET used in a power conversion circuit which includes at least a reactor, a power source which supplies an electric current to the reactor, the MOSFET for controlling an electric current supplied from the power source to the reactor, and a rectifier element which performs a rectifying operation of the electric current supplied from the power source to the reactor or an electric current from the reactor, wherein
the MOSFET includes a semiconductor base substrate including an n-type column region and a p-type column region, the n-type column region and the p-type column region forming a super junction structure,
the n-type column region and the p-type column region are formed such that a total amount of a dopant in the n-type column region is set higher than a total amount of a dopant in the p-type column region, and
the MOSFET is configured to be operated during a period from a point of time when a drain current starts to decrease to a point of time when the drain current becomes 0 for the first time in response to turning off of the MOSFET such that a first period during which the drain current decreases, a second period during which the drain current increases, and a third period during which the drain current decreases again appear in this order.

2. The MOSFET according to claim 1, wherein the total amount of the dopant in the n-type column region is set in a range of 1.05 times to 1.15 times as much as the total amount of the dopant in the p-type column region.

3. The MOSFET according to claim 1, wherein a decrease amount of the drain current per unit time during the third period is set smaller than a decrease amount of the drain current per unit time during the first period.

4. The MOSFET according to claim 1, wherein the MOSFET is configured to be operated such that, in response to turning off of the MOSFET, a period during which a gate-source voltage is temporarily increased appears after a mirror period is finished.

5. The MOSFET according to claim 1, wherein the semiconductor base substrate further includes: a p-type base region formed on a surface of the n-type column region and a surface of the p-type column region; and an n-type source region formed on a surface of the base region, and
the MOSFET is a trench-gate-type MOSFET which further includes: a trench where the trench is formed so as to reach a depth position deeper than a deepest portion of the base region in a region where the n-type column region is positioned as viewed in a plan view, and a portion of the source region is exposed on an inner peripheral surface of the trench; and
a gate electrode embedded in the inside of the trench by way of a gate insulation film formed on the inner peripheral surface of the trench.

6. The MOSFET according to claim 1, wherein the semiconductor base substrate further includes: a p-type base region formed on a surface of a portion of the n-type column region and a whole surface of the p-type column region; and an n-type source region formed on a surface of the base region, and
the MOSFET is a planar-gate-type MOSFET which further includes a gate electrode formed on the base region sandwiched between the source region and the n-type column region by way of a gate insulation film.

7. The MOSFET according to claim 6, wherein the semiconductor base substrate further includes an n-type surface high concentration diffusion region formed on a portion of the surface of the n-type column region where the base region is not formed.

8. The MOSFET according to claim 1, wherein in the p-type column region, in a depth direction of the p-type column region, a width of the p-type column region is increased as the p-type column region extends from a deep portion of the p-type column region toward a surface of the p-type column region.

9. The MOSFET according to claim 1, wherein in the p-type column region, in a depth direction of the p-type column region, dopant concentration in the p-type column region is increased as the p-type column region extends from a deep portion of the p-type column region toward a surface of the p-type column region.

10. A power conversion circuit comprising at least:
a reactor;
a power source which supplies an electric current to the reactor;
the MOSFET according to claim 1 for controlling an electric current supplied from the power source to the reactor, and
a rectifier element which performs a rectifying operation of the electric current supplied from the power source to the reactor or an electric current from the reactor.

11. The power conversion circuit according to claim 10, wherein the rectifier element is a fast recovery diode.

12. The power conversion circuit according to claim 10, wherein the rectifier element is a built-in diode of the MOSFET.

13. The power conversion circuit according to claim 10, wherein the rectifier element is a silicon-carbide Schottky barrier diode.
